(19) United States
(12) Patent Application Publication
(10) Pub. No.: US 2004/0106240 A1
(43) Pub. Date: Jun. 3, 2004

(54) Process for forming polysilicon layer and fabrication of thin film transistor by the process

(75) Inventors: Chia-Tien Peng, Jubei City (TW); Long-Sheng Liao, Jungli City (TW); Yi-Chang Tsao, Hsinchu (TW)

Correspondence Address: Richard P. Berg, Esq., c/o LADAS & PARRY, Suite 2100, 5670 Wilshire Boulevard, Los Angeles, CA, 90036-5679, US

(73) Assignee: AU Optronics Corp.

(21) Appl. No.: 10/410,041

(22) Filed: Apr. 8, 2003

(30) Foreign Application Priority Data
Nov. 28, 2002 (TW) 91134674

(51) Int. Cl. H01L 21/00; H01L 21/84

(52) U.S. Cl. 438/166

(57) ABSTRACT

A process for forming a polysilicon layer. First, an amorphous silicon layer is formed. Next, the amorphous silicon layer is pre-treated such that a surface of the amorphous silicon layer is oxidized to a silicon oxide layer or nitridized to a silicon nitride layer. Next, the amorphous silicon layer is crystallized to form a polysilicon layer. TFT fabricated by the present invention has smaller Vt and higher electron mobility.

### BACKGROUND OF THE INVENTION

1. Field of the Invention

The present invention relates to a process for forming a polysilicon layer, and more particularly to a process for forming a polysilicon layer with a relatively larger grain size.

2. Description of the Prior Art

Polysilicon thin film transistor (poly-Si TFT) has higher electron mobility, quicker response time, and higher resolution than amorphous silicon TFT. Therefore, poly-Si TFT has been extensively applied in LCD technology to drive LCDs. Generally, poly-Si TFT is fabricated by the low temperature polysilicon (LTPS) process.

FIGS. 1a to 1c are cross-sections illustrating the process flow of forming a polysilicon layer by LTPS in the conventional TFT array fabrication. Referring to FIG. 1a, a barrier layer 120 and an amorphous silicon layer 200 are formed sequentially on a substrate 100.

Subsequently, the amorphous silicon layer 200 is crystallized by, for example, excimer laser annealing (ELA). Referring to FIG. 1b, after laser irradiation, the amorphous silicon layer 200 is melted into amorphous silicon liquid 220. When amorphous silicon liquid 220 is cooled, nucleation centers (shown as dots in FIG. 1b) are generated at the interface between amorphous silicon liquid 220/barrier layer 120. Thus, amorphous silicon liquid 220 will gradually crystallize along the nucleation centers to form a polysilicon layer 300 as shown in FIG. 1c.

As mentioned above, if the amorphous silicon is not subjected to pre-treatment prior to crystallization, the polysilicon layer 300 obtained will have a small grain size and a very narrow process window. When the subsequent process is conducted to complete TFT, the polysilicon layer with small grain size causes the resulting TFT to have a higher Vt (threshold voltage) and a lower electron mobility.

### SUMMARY OF THE INVENTION

An object of the present invention is to solve the above-mentioned problems and provide a process for forming a polysilicon layer with a large grain size. TFT fabricated by the present invention has a lower Vt and higher electron mobility.

To achieve the above object, the process of forming a polysilicon layer according to the present invention includes the following steps. First, an amorphous silicon layer is formed. Next, the amorphous silicon layer is pre-treated such that a surface of the amorphous silicon layer is oxidized to a silicon oxide layer or nitridized to a silicon nitride layer. Next, the amorphous silicon layer is crystallized to form a polysilicon layer.

### BRIEF DESCRIPTION OF THE DRAWINGS

The present invention will become more fully understood from the detailed description given hereinbelow and the accompanying drawings, given by way of illustration only and thus not intended to be limitative of the present invention.

FIGS. 1a to 1c are cross-sections illustrating the process flow of forming a polysilicon layer in conventional TFT array fabrication.

FIGS. 2a to 2d are cross-sections illustrating the process flow of forming a polysilicon layer according to a preferred embodiment of the present invention.

FIGS. 3a to 3f are cross-sections illustrating the process flow of fabricating a top-gate polysilicon NTFT according to a preferred embodiment of the present invention.

FIG. 4 shows the relationship between the grain size of the obtained polysilicon layer with or without pre-treatment and the laser energy density, in which the polysilicon layer is obtained with pre-treatment to the amorphous silicon layer according to the present invention or without pre-treatment according to the conventional method and then with laser irradiation.

FIG. 5 shows Id-Vg diagrams of NTFT obtained by the present inventive pre-treatment and the conventional method.

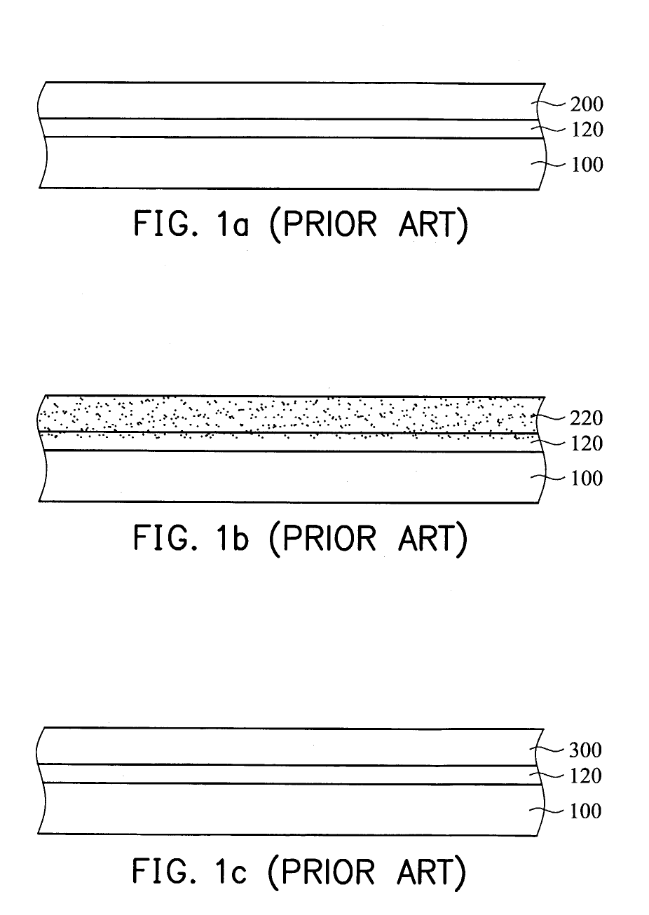

### DETAILED DESCRIPTION OF THE INVENTION

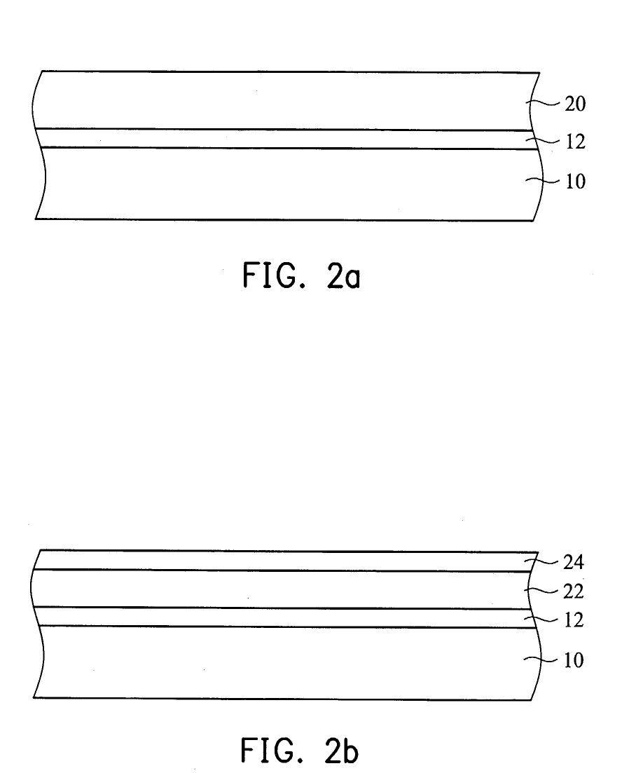

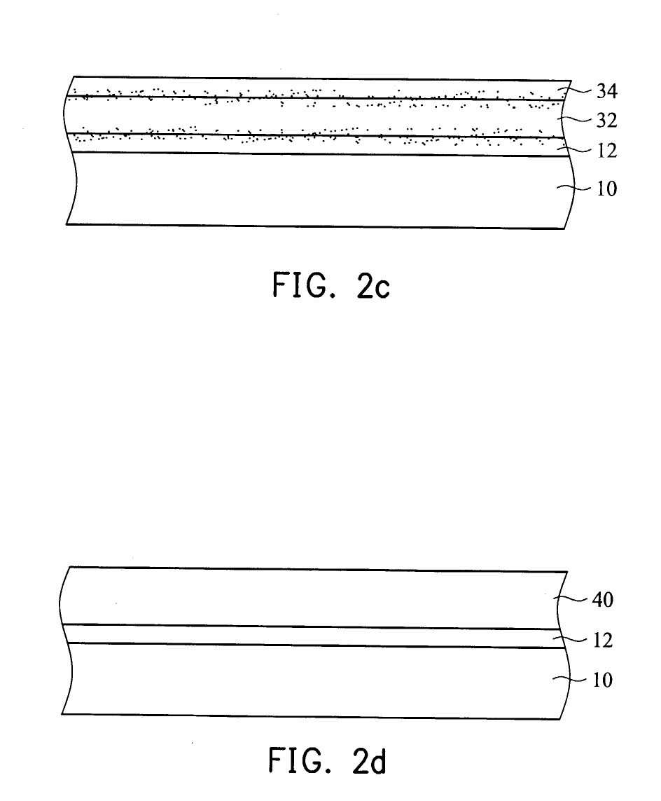

FIGS. 2a to 2d are cross-sections illustrating the process flow of forming a polysilicon layer according to a preferred embodiment of the present invention. Referring to FIG. 2a, a barrier layer 12 and an amorphous silicon layer 20 are formed sequentially on a substrate 10.

Subsequently, referring to FIG. 2b, the amorphous silicon layer 20 is pre-treated such that the surface of the amorphous silicon layer 20 is oxidized to a silicon oxide layer 24 or nitridized to a silicon nitride layer 24. The silicon oxide layer or silicon nitride layer 24 can have a thickness of 1 Å to 50 Å, preferably 5 Å to 25 Å. Due to surface oxidation or nitridation, the original amorphous silicon layer 20 thins and the thinned amorphous silicon layer is labeled as 22.

For surface oxidation of the amorphous silicon layer 20, the pre-treatment prior to crystallization of the present invention can use oxygen-containing plasma to treat the amorphous silicon layer 20, forming a silicon oxide layer. The oxygen-containing plasma can be N₂O plasma. Or, alternatively, the amorphous silicon layer 20 can be immersed in an oxygen-containing solution to form a silicon oxide layer. The oxygen-containing solution can be hydrogen peroxide (H₂O₂) or ozone (O₃) water. Irradiation with a UV lamp can also be used. For example, the surface of the amorphous silicon layer can be irradiated with a UV lamp in an air medium to form a silicon oxide layer. Also, the surface of the amorphous silicon layer can be baked in a furnace or oven to form a silicon oxide layer.

For surface nitridation of the amorphous silicon layer 20, the present inventive pre-treatment prior to crystallization can use nitrogen-containing plasma to treat the amorphous silicon layer 20, forming a silicon nitride layer. The nitrogen-containing plasma can be N₂ plasma or NH₃ plasma. Or, the amorphous silicon layer 20 can be immersed in a nitrogen-containing solution to form a silicon nitride layer. Or, the surface of the amorphous silicon layer can be baked with a furnace or oven to form a silicon nitride layer.

For better understanding, we take the formation of a silicon nitride layer 24 by surface nitridation of amorphous silicon layer as an example. Next, the amorphous silicon layer 22 is crystallized. Various conventional processes can be used for crystallization, including excimer laser annealing (ELA) at low temperature, solid phase crystallization (SPC) at high temperature, continuous grain growth (CGC), metal induced crystallization (MIC), metal induced lateral crystallization (MILC), and sequential lateral solidification (SLS). Referring to FIG. 2c, after irradiated by laser, the amorphous silicon layer 22 melts into amorphous silicon liquid 32. During cooling, nucleation centers (as shown in dots in FIG. 2c) are generated at the interface between amorphous silicon liquid 32/barrier layer 12 and at the interface between amorphous silicon liquid/silicon nitride solid 34. Thus, amorphous silicon liquid 32 will gradually crystallize along the nucleation centers, forming a polysilicon layer 40 as shown in FIG. 2d.

As mentioned above, in the conventional process, the amorphous silicon layer is not subjected to pre-treatment prior to crystallization and no additional silicon nitride layer is formed. Therefore, the crystallization time is shorter. In contrast, in the present process, the amorphous silicon layer is pre-treated prior to crystallization, thus forming a silicon nitride layer. This silicon nitride layer will lengthen the crystallization time, thus obtaining a larger grain size. Therefore, the polysilicon layer 40 formed in the present invention has a larger grain size and the process window is wider.

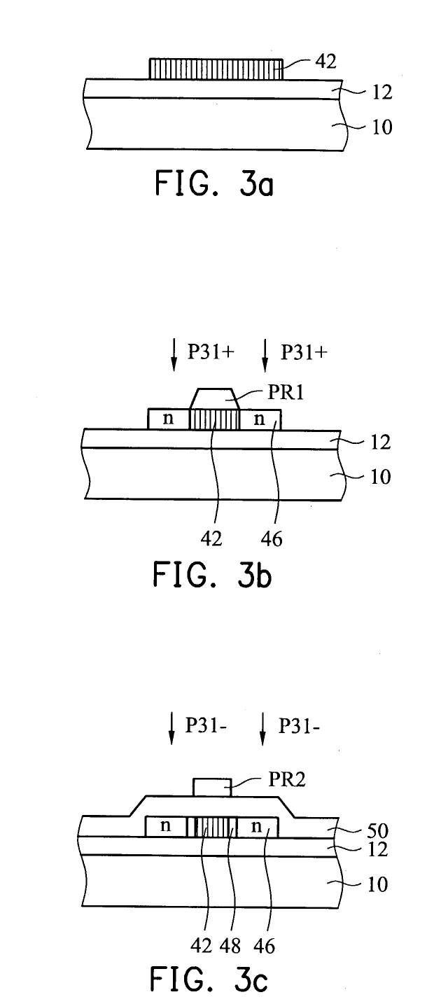

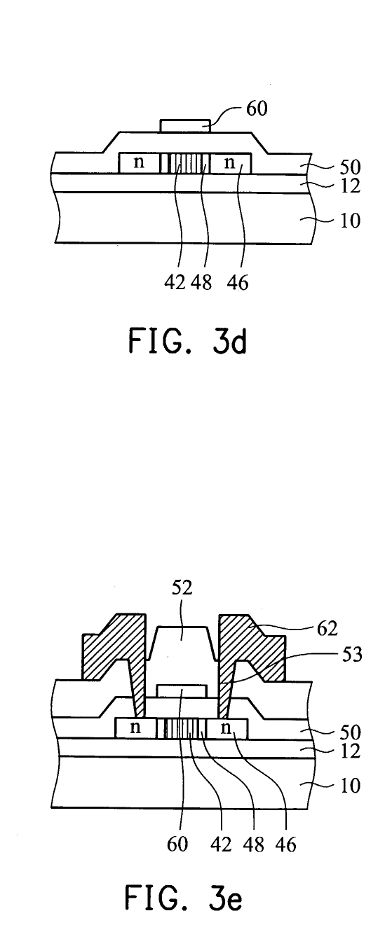

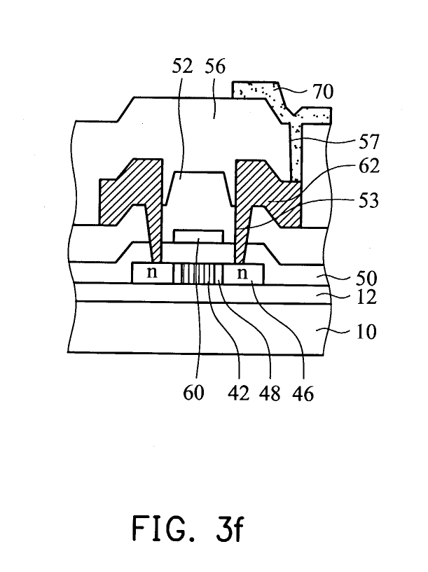

FIGS. 3a to 3f are cross-sections illustrating the process flow of fabricating a top-gate polysilicon NTFT according to a preferred embodiment of the present invention.

First, according to the steps mentioned in FIGS. 2a to 2d, a barrier layer 12 and an amorphous silicon layer (not shown) are formed sequentially on a substrate. Next, the amorphous silicon layer is pre-treated such that the surface of the amorphous silicon layer is nitridized to a silicon nitride layer, and then crystallized to form a polysilicon layer (not shown). Next, the polysilicon layer is patterned to form a polysilicon layer 42 as shown in FIG. 3a. The substrate 10 can be a transparent substrate such as glass or plastic. The barrier layer 12 can be a silicon nitride or silicon oxide layer, or, alternatively, can include two layers: a combination of a silicon nitride and silicon oxide layers. The amorphous silicon layer can be formed by plasma-enhanced chemical vapor deposition (PECVD) or low pressure chemical vapor deposition (LPCVD) using silane (SiH₄) as reactant gas.

Subsequently, referring to FIG. 3b, a photoresist pattern PR1 is formed and then the polysilicon layer 42 is heavily doped with phosphorus using the photoresist pattern PR1 as a mask, forming an n-type source/drain region 46. Next, referring to FIG. 3c, the photoresist pattern PR1 is removed, and then a gate dielectric layer 50 and a photoresist pattern PR2 are formed. The polysilicon layer 42 is lightly doped with phosphorus using the photoresist pattern PR2 as a mask, forming a lightly-doped drain (LDD) 48 at the inner side of the n-type source/drain region 46.

Subsequently, referring to FIG. 3d, the photoresist pattern PR2 is removed. Next, a metal layer (not shown) is formed on the gate dielectric layer 50 and then subjected to photolithography and etching to form a gate layer 60 at the position corresponding to the polysilicon layer 42. Thus far, NTFT is complete.

Subsequently, referring to FIG. 3e, an interlayer dielectric layer 52 is formed and then a first opening 53 reaching the source/drain region 46 is formed in the interlayer dielectric layer 52. Next, metal is filled in the first opening 53 to form a source/drain electrode 62.

Subsequently, referring to FIG. 3f, a passivation layer 56 is formed and then a second opening 57 reaching the drain electrode 62 of NTFT is formed in the passivation layer 56. Next, a pixel electrode 70 such as indium-tin-oxide (ITO) is filled in the second opening 57. Thus far, TFT array fabrication is complete, and the TFT array as shown in FIG. 3f is obtained. The TFT array can be combined with a front transparent substrate (such as a color filter substrate) and liquid crystal to make up a TFT-LCD panel.

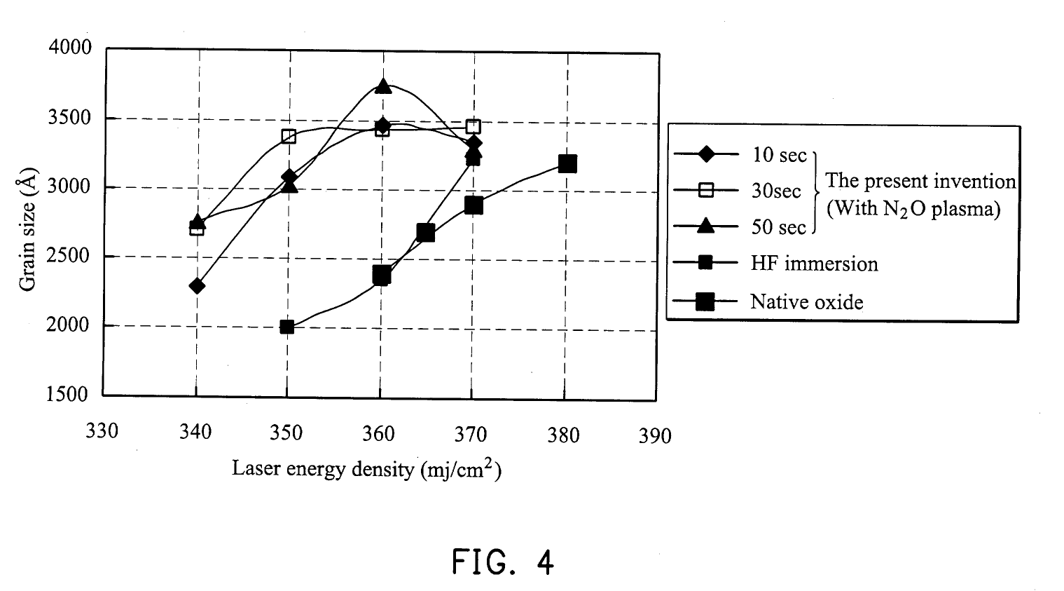

As described above, the amorphous silicon layer is pre-treated according to the present invention or not pre-treated according to the conventional method, and is then crystallized by irradiating with different laser energy density to form a polysilicon layer. FIG. 4 shows the relationship between the grain size of the obtained polysilicon layer with or without pre-treatment and the laser energy density. Before laser irradiation, the present invention pre-treats the amorphous silicon layer using 0.078 W/cm² N₂O plasma for 10, 30, and 50 seconds. The conventional method does not pre-treat the amorphous silicon layer. It can be seen from FIG. 4 that with the pre-treatment of the present invention, the grain size of the polysilicon is large and uniform over a very wide laser energy density range (350-370 mj/cm²), indicating a large process window. In contrast, with the conventional method, the grain size of the polysilicon is very small and varies greatly over various laser energy densities, indicating a small process window.

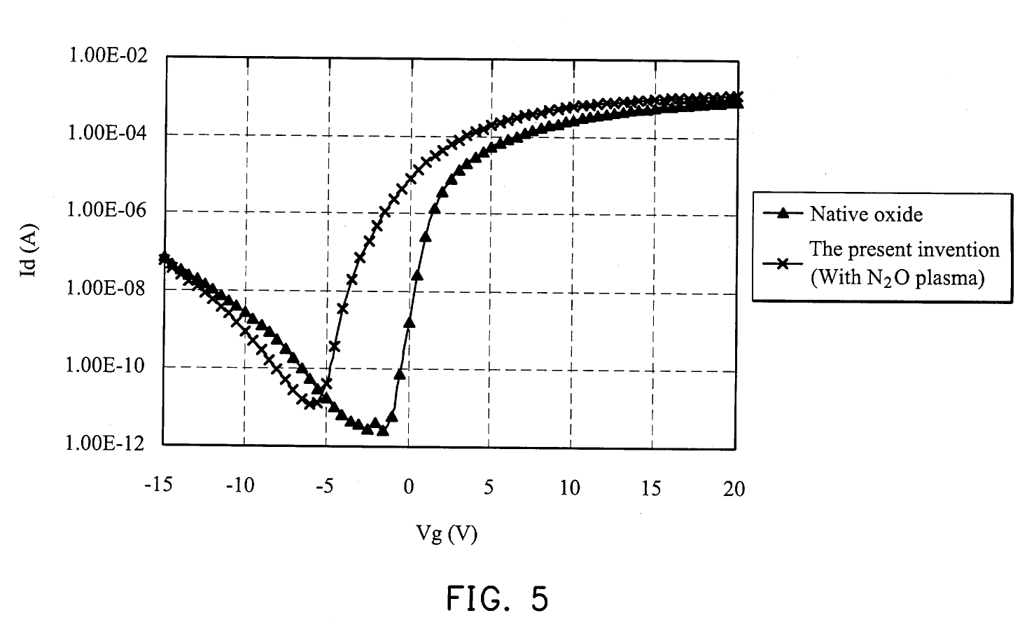

Table 1 shows electrical data of NTFT fabricated by the present inventive pre-treatment and by the conventional method. FIG. 5 shows Id-Vg diagrams of NTFT fabricated by present inventive pre-treatment and by the conventional method. The present invention pre-treats the amorphous silicon layer using 0.078 W/cm² N₂O plasma for 50 seconds, forming a silicon nitride layer of 20 Å thick. The conventional method does not pre-treat the amorphous silicon layer.

TABLE 1
Electrical data of NTFT

| | | The present |
|---|---|---|
| | | invention |
| | | (N₂O pre-treament |
| | Conventional | to amorphous |
| | method | silicon) |
| Vt (V) | 1.71 | 0.91 |
| Ufe (cm²/Vs) | 61 | 138 |
| SS (mV/decade) | 0.5 | 0.5 |

Vt: threshold voltage
Ufe: field effect mobility
SS: subthreshold swing

It can be seen from Table 1 and FIG. 5 that TFT fabricated by the pre-treatment prior to crystallization of the present invention has good electrical properties, smaller Vt, and higher electron mobility.

The foregoing description of the preferred embodiments of this invention has been presented for purposes of illustration and description. Obvious modifications or variations are possible in light of the above teaching. The embodiments chosen and described provide an excellent illustration of the principles of this invention and its practical application to thereby enable those skilled in the art to utilize the invention in various embodiments and with various modifications as are suited to the particular use contemplated. All such modifications and variations are within the scope of the present invention as determined by the appended claims when interpreted in accordance with the breadth to which they are fairly, legally, and equitably entitled.

What is claimed is:

1. A process for forming a polysilicon layer, comprising the following steps:
forming an amorphous silicon layer;
pre-treating the amorphous silicon layer such that a surface of the amorphous silicon layer is oxidized to a silicon oxide layer or nitridized to a silicon nitride layer; and
crystallizing the amorphous silicon layer to form a polysilicon layer.

2. The process as claimed in claim 1, wherein the pre-treating step oxidizes the surface of the amorphous silicon layer to the silicon oxide layer.

3. The process as claimed in claim 1, wherein the pre-treating step nitridizes the surface of the amorphous silicon layer to the silicon nitride layer.

4. The process as claimed in claim 2, wherein the pre-treating step is conducted by treating the amorphous silicon layer with oxygen-containing plasma to form the silicon oxide layer.

5. The process as claimed in claim 4, wherein the oxygen-containing plasma is N₂O plasma.

6. The process as claimed in claim 2, wherein the pre-treating step is conducted by immersing the amorphous silicon layer in an oxygen-containing solution to form the silicon oxide layer.

7. The process as claimed in claim 6, wherein the oxygen-containing solution is hydrogen peroxide (H₂O₂) or ozone (O₃) water.

8. The process as claimed in claim 2, wherein the pre-treating step is conducted by irradiating the surface of the amorphous silicon layer with a UV lamp in an air medium to form the silicon oxide layer.

9. The process as claimed in claim 2, wherein the pre-treating step is conducted by baking the surface of the amorphous silicon layer in a furnace or oven to form the silicon oxide layer.

10. The process as claimed in claim 3, wherein the pre-treating step is conducted by treating the amorphous silicon layer with nitrogen-containing plasma to form the silicon nitride layer.

11. The process as claimed in claim 10, wherein the nitrogen-containing plasma is N₂ plasma or NH₃ plasma.

12. The process as claimed in claim 3, wherein the pre-treating step is conducted by immersing the amorphous silicon layer in a nitrogen-containing solution to form the silicon nitride layer.

13. The process as claimed in claim 3, wherein the pre-treating step is conducted by baking the surface of the amorphous silicon layer with a furnace or oven to form the silicon nitride layer.

14. The process as claimed in claim 1, wherein the silicon oxide layer or silicon nitride layer has a thickness of 1 Å to 50 Å.

15. The process as claimed in claim 14, wherein the silicon oxide layer or silicon nitride layer has a thickness of 5 Å to 25 Å.

16. A process for fabricating a polysilicon thin film transistor, comprising the following steps:
forming an amorphous silicon layer on a substrate;
pre-treating the amorphous silicon layer such that a surface of the amorphous silicon layer is oxidized to a silicon oxide layer or nitridized to a silicon nitride layer;
crystallizing the amorphous silicon layer to form a polysilicon layer as an active layer; and
forming a gate dielectric layer, a gate, a source region and a drain region.

17. The process as claimed in claim 16, wherein the pre-treating step oxidizes the surface of the amorphous silicon layer to the silicon oxide layer.

18. The process as claimed in claim 16, wherein the pre-treating step nitridized the surface of the amorphous silicon layer to the silicon nitride layer.

19. The process as claimed in claim 17, wherein the pre-treating step is conducted by treating the amorphous silicon layer with oxygen-containing plasma to form the silicon oxide layer.

20. The process as claimed in claim 19, wherein the oxygen-containing plasma is N₂O plasma.

21. The process as claimed in claim 17, wherein the pre-treating step is conducted by immersing the amorphous silicon layer in an oxygen-containing solution to form the silicon oxide layer.

22. The process as claimed in claim 21, wherein the oxygen-containing solution is hydrogen peroxide (H₂O₂) or ozone (O₃) water.

23. The process as claimed in claim 17, wherein the pre-treating step is conducted by irradiating the surface of the amorphous silicon layer with a UV lamp in an air medium to form the silicon oxide layer.

24. The process as claimed in claim 17, wherein the pre-treating step is conducted by baking the surface of the amorphous silicon layer in a furnace or oven to form the silicon oxide layer.

25. The process as claimed in claim 18, wherein the pre-treating step is conducted by treating the amorphous silicon layer with nitrogen-containing plasma to form the silicon nitride layer.

26. The process as claimed in claim 25, wherein the nitrogen-containing plasma is N₂ plasma or NH₃ plasma.

27. The process as claimed in claim 18, wherein the pre-treating step is conducted by immersing the amorphous silicon layer in a nitrogen-containing solution to form the silicon nitride layer.

28. The process as claimed in claim 18, wherein the pre-treating step is conducted by baking the surface of the amorphous silicon layer with a furnace or oven to form the silicon nitride layer.

29. The process as claimed in claim 16, wherein the silicon oxide layer or silicon nitride layer has a thickness of 1 Å to 50 Å.

30. The process as claimed in claim 29, wherein the silicon oxide layer or silicon nitride layer has a thickness of 5 Å to 25 Å.
